(19) United States
(12) Patent Application Publication
(10) Pub. No.: US 2010/0110605 A1
(43) Pub. Date: May 6, 2010

(54) ELECTROSTATIC CHUCK ASSEMBLY FOR PLASMA REACTOR

(76) Inventors: Weonmook LEE, Suwon-si (KR); Hwankook CHAE, Suwon-si (KR); Kunjoo PARK, Suwon-si (KR); Sungyong KO, Suwon-si (KR); Minshik KIM, Seoul (KR); Keehyun KIM, Suwon-si (KR)

Correspondence Address: IPLA P.A., 3550 WILSHIRE BLVD., 17TH FLOOR, LOS ANGELES, CA, 90010, US

(21) Appl. No.: 12/580,029

(22) Filed: Oct. 15, 2009

(30) Foreign Application Priority Data
Nov. 5, 2008 (KR) 10-2008-0109242

(51) Int. Cl. H01L 21/683

(52) U.S. Cl. 361/234

(57) ABSTRACT

Provided is an electrostatic chuck assembly for a plasma reactor. The assembly includes an electrostatic chuck, an electrostatic chuck cover ring, and a cathode assembly cover ring. The electrostatic chuck includes a body part and a protrusion part. The body part has a disk shape of a first diameter. The protrusion part is formed integrally with the body part and protrudes from the body part, and has a disk shape of a second diameter less than the first diameter. The electrostatic chuck cover ring is disposed to surround an outer circumference of the protrusion part. The cathode assembly cover ring is disposed at an upper part of the cathode assembly to surround an outer circumference of the electrostatic chuck cover ring and an outer circumference of the body part.

### CROSS REFERENCE

This application claims foreign priority under Paris Convention and 35 U.S.C. §119 to each of Korean Patent Application No. 10-2008-0109242, filed 5 Nov. 2008 with the Korean Intellectual Property Office.

### BACKGROUND OF THE INVENTION

1. Field of the Invention

The present invention relates to a plasma reactor used in a semiconductor manufacturing process. More particularly, the present invention relates to an electrostatic chuck assembly of the plasma reactor.

2. Description of the Related Art

In general, an electrostatic chuck is positioned on a cathode assembly installed within a reaction chamber of a plasma reactor. Within the reaction chamber, the electrostatic chuck is used to fix a target object (e.g., a wafer or glass substrate) to be etched or deposited with etching material, to a cathode assembly. The target object is fixed to an upper part of the electrostatic chuck by an electrostatic attractive force that is generated when a Direct Current (DC) power source is supplied to the electrostatic chuck. In order to smoothly etch the target object within the reaction chamber, the target object has to be fixed to the upper part of the electrostatic chuck firmly, e.g., enough to endure a pressure of Helium (He) gas of 30 Torr or more applied to a rear surface side of the target object.

In designing and manufacturing an electrostatic chuck assembly, the most important item is to protect the electrostatic chuck from plasma ions. A design for protecting the electrostatic chuck is most important to lengthen the lifetime of a process kit around the electrostatic chuck and decrease an economical loss. In general, the lifetime of the electrostatic chuck should be kept until the plasma reactor performs a wafer treatment process of at least one hundred thousand cycles. The lifetime of the electrostatic chuck and the process kit around the electrostatic chuck can be lengthened or shortened depending on a structure of the electrostatic chuck assembly. Also, operation performance (particularly, etching performance) of the plasma reactor can vary depending on the structure of the electrostatic chuck assembly.

Compared to a chemical etching process, an oxide film etching process using physical impact for applying physical energy to plasma ions and etching a surface of a wafer is much affected by a change of the structure of the electrostatic chuck assembly. That is, the oxide film etching process can be improved or deteriorated in quality depending on the structure of the electrostatic chuck assembly or the etching performance of the plasma reactor. Accordingly, the structure of the electrostatic chuck assembly should be optimized to lengthen the lifetime of the electrostatic chuck and improve the etching performance of the plasma reactor.

FIG. 1 is a schematic diagram illustrating a conventional electrostatic chuck assembly. For simplification of the drawings, illustration of a cathode assembly is omitted in FIG. 1. The electrostatic chuck assembly 10 includes an electrostatic chuck 20, a Radio Frequency (RF) couple ring 30, an electrostatic chuck cover ring 40, and a cathode assembly cover ring 50. The RF couple ring 30 and the electrostatic chuck cover ring 40 surround an outer circumference of an upper part of the electrostatic chuck 20. The electrostatic chuck cover ring 40 is positioned on an upper part of the RF couple ring 30. Because the RF couple ring 30 and the electrostatic chuck cover ring 40 are fitted to the outer circumference of the upper part of the electrostatic chuck 20, the upper part of the electrostatic chuck 20 should be designed to have a protruded length (D) of at least 10 mm or more.

The RF couple ring 30 can be of metal material such as aluminum, etc. The cathode assembly cover ring 50 surrounds outer circumferences of the RF couple ring 30 and the electrostatic chuck cover ring 40 and an outer circumference of a lower part of the electrostatic chuck 20. A wafer 80 is safely mounted on a surface of a top of the electrostatic chuck 20. When a DC power source is supplied to the electrostatic chuck 20, static electricity is generated in the electrostatic chuck 20 and as a result, the wafer 80 is fixed to the surface of the top of the electrostatic chuck 20. A power supply unit 60 supplies the DC power source to the electrostatic chuck 20 through a RF noise filter 70.

A dry etching process of a plasma reactor is briefly described below. A target object such as the wafer 80, etc. is conveyed to the top of the electrostatic chuck 20 within a reaction chamber. If so, a reaction gas is injected into the reaction chamber, and a vacuum system is activated to maintain the internal of the reaction chamber at a constant vacuum degree. Then, if the internal of the reaction chamber reaches a vacuum degree suitable to an etching process, an RF power is applied to an inductive coil of the plasma reactor, a bias RF power is supplied to a lower electrode (i.e., a cathode), and a DC power source is supplied to the electrostatic chuck 20. As a result, as illustrated in FIG. 1, plasma ions 91 and 92 apply physical impacts to a surface of the wafer 80 and at the same time, a chemical reaction between the plasma ions 91 and 92 and the wafer 80 occurs. At this time, the RF power is supplied even to the RF couple ring 30 and resultantly, the plasma ions 92 are incident on a surface of the electrostatic chuck cover ring 40 in an almost perpendicular direction.

If the RF power is not or insufficiently supplied to the RF couple ring 30, as indicated by a dotted line arrow, the plasma ions 92 are incident on an edge of the wafer 80 and the electrostatic chuck cover ring 40 in a slant direction having a constant angle (θ) on the basis of a direction (i.e., a solid line arrow) perpendicular to the surface of the electrostatic chuck cover ring 40. The reason is that a bias power (i.e., energy of the plasma ions 91 and 92) on a top surface of the electrostatic chuck 20 (i.e., on a surface of the electrostatic chuck 20 contacting with the wafer 80) is greater than a bias power on a surface of the electrostatic chuck 20 contacting with a bottom surface of the RF couple ring 30. Accordingly, the plasma ions 92 incident on the edge of the electrostatic chuck 20 are incident toward the top surface of the electrostatic chuck 20.

Because the angle (θ) can vary depending on a degree of an attractive force by which the RF couple ring 30 attracts the plasma ions 92, for the sake of improving a process quality at the edge of the wafer 80 and lengthening the lifetime of the electrostatic chuck cover ring 40, it is important that the RF couple ring 30 is installed on the surface of the electrostatic chuck 20 such that the RF couple ring 30 attracts the plasma ions 92 by a suitable attractive force.

However, the RF couple ring 30 is not fully adhered between a surface of the electrostatic chuck 20 and the electrostatic chuck cover ring 40 but is simply fitted, i.e., floated between the electrostatic chuck 20 and the electrostatic chuck cover ring 40. Thus, although the RF couple ring 30 is enabled, it is almost impossible that the plasma ions 92 are perpendicularly incident on the surface of the electrostatic chuck cover ring 40.

Also, the RF couple ring 30 is not fully adhered between the surface of the electrostatic chuck 20 and the electrostatic chuck cover ring 40. Thus, there are secondary problems such as shortening the lifetime of the electrostatic chuck cover ring 40 resulting from the slant incidence of the plasma ions, increasing an arcing phenomenon of the electrostatic chuck, increasing the number of particles, shortening a cleaning period of the reaction chamber, etc.

The plasma ions 92 are incident on the edge of the wafer 80 in the slant direction having the constant angle (θ), thus deteriorating a process quality at the edge of the wafer 80. FIG. 2 illustrates the wafer 80 dry-etched within the reaction chamber with an RF power not supplied to the RF couple ring 30. After the wafer 80 is cut along a cutting line C-C′, when viewing its cut surface, a profile of contact holes (H1 to H3) formed in the wafer 80 is illustrated in a lower part of FIG. 2. It can be appreciated from FIG. 2 that the contact hole (H2) formed in a center of the wafer 80 has a normal profile perpendicular to a bottom surface of the wafer 80 but, as the plasma ions 92 are incident on the slant, the contact holes (H1 and H3) formed in the edge of the wafer 80 are inclined and thus have an abnormal profile.

If the plasma ions 92 are incident on the electrostatic chuck cover ring 40 in the slant direction having the constant angle (θ), the electrostatic chuck cover ring 40 is abnormally etched and thus, the lifetime of the electrostatic chuck cover ring 40 can be suddenly shortened. Referring to FIG. 1, as the plasma reactor performs wafer treatment processes repeatedly, a new or non-etched electrostatic chuck cover ring 40 (an ‘A’ portion) is gradually etched. At this time, if an etching process is performed with the RF power not supplied to the RF couple ring 30, the electrostatic chuck cover ring 40′ can be abnormally etched as illustrated in an ‘A′’ portion of FIG. 1. In order to prevent abnormal etching of the electrostatic chuck cover ring 40′ and improve a quality of an etching process at the edge of the wafer 80, the electrostatic chuck assembly 10 has to inevitably include the RF couple ring 30. Thus, because including the RF couple ring 30, the conventional electrostatic chuck assembly 10 has a problem that its structure is complex and also its manufacturing cost increases. Also, although the electrostatic chuck assembly 10 includes the RF couple ring 30, it is very difficult to completely operate the RF couple ring 30, i.e., to perform an operation of making the plasma ions 92 be perpendicularly incident on the surface of the electrostatic chuck cover ring 40. Thus, the electrostatic chuck assembly 10 still has an incomplete coupling problem of the RF couple ring 30.

### SUMMARY OF THE INVENTION

An aspect of exemplary embodiments of the present invention is to address at least the problems and/or disadvantages and to provide at least the advantages described below. Accordingly, an aspect of exemplary embodiments of the present invention is to provide an electrostatic chuck assembly for overcoming an incomplete coupling problem of a Radio Frequency (RF) couple ring and at the same time, by minimizing an incidence angle (θ) of plasma ions and optimizing a structure of the electrostatic chuck assembly such that the plasma ions are perpendicularly incident on a surface of an electrostatic chuck cover ring at an edge of an electrostatic chuck, making the RF couple ring unnecessary, lengthening the lifetime of the electrostatic chuck cover ring, and improving etching performance of a plasma reactor.

To achieve these and other advantages in accordance with the purpose of the present invention, there is provided an electrostatic chuck assembly for a plasma reactor. The electrostatic chuck assembly includes an electrostatic chuck, an electrostatic chuck cover ring, and a cathode assembly cover ring. The electrostatic chuck includes a body part and a protrusion part. The body part has a disk shape of a first diameter. The protrusion part is formed integrally with the body part and protrudes from the body part, and has a disk shape of a second diameter less than the first diameter. The electrostatic chuck cover ring is disposed to surround an outer circumference of the protrusion part, and protects the body part of the electrostatic chuck from plasma ions generated as the plasma reactor operates. The cathode assembly cover ring is disposed at an upper part of the cathode assembly to surround an outer circumference of the electrostatic chuck cover ring and an outer circumference of the body part. In order to allow the electrostatic chuck cover ring to have a cut surface of an ‘L’ shape after the electrostatic chuck cover ring is etched by the plasma ions, a length (G) of the protrusion part protruding from the body part is set to be in the range of 1.0 mm≦G≦7.0 mm irrespective of a diameter of a target object safely mounted on an upper surface of the protrusion part.

As described above, the electrostatic chuck assembly according to the present invention optimizes its structure, particularly, a structure of the electrostatic chuck, thereby being able to overcome an incomplete coupling problem of an RF couple ring and at the same time, by minimizing an incidence angle (θ) of plasma ions at an edge of the electrostatic chuck and making the plasma ions be perpendicularly incident on a surface of the electrostatic chuck cover ring at the edge of the electrostatic chuck, make installation of the RF couple ring unnecessary, lengthen the lifetime of the electrostatic chuck cover ring, and improve etching performance of a plasma reactor.

Also, by optimizing a length (G) of a protrusion part of the electrostatic chuck and a diameter (R1) of the protrusion part, there is no need to specifically design a shape of a focus ring outside the electrostatic chuck cover ring or add a complex additional element such as the RF couple ring to a lower part of the electrostatic chuck cover ring, thus being able to decrease an equipment manufacturing cost of a plasma reactor. On the other hand, by optimizing the length (G) of the protrusion part of the electrostatic chuck and the diameter (R1) of the protrusion part, protection of the electrostatic chuck and a process quality of an edge of a target object (i.e., a wafer) can be guaranteed.

Also, by optimizing the length (G) of the protrusion part of the electrostatic chuck and the diameter (R1) of the protrusion part, an etching profile of the electrostatic chuck cover ring has an ‘L’ shape (indicated by a B′ portion of FIG. 3) and thus, is able to obtain an effect of an equipment maintenance side such as lengthening the lifetime of the electrostatic chuck cover ring, decreasing an arcing phenomenon of the electrostatic chuck, decreasing the number of particles, lengthening a cleaning period of the reaction chamber, etc.

### BRIEF DESCRIPTION OF THE DRAWINGS

The above and other objects, features and advantages of the present invention will become more apparent from the following detailed description when taken in conjunction with the accompanying drawings in which:

FIG. 1 is a schematic diagram illustrating a conventional electrostatic chuck assembly;

FIG. 2 is a diagram illustrating a wafer etched by a plasma reactor including the electrostatic chuck assembly of FIG. 1;

FIG. 3 is a schematic diagram illustrating an electrostatic chuck assembly according to an exemplary embodiment of the present invention;

FIG. 4 is a side diagram of an electrostatic chuck illustrated in FIG. 3;

FIG. 5 is a plan diagram of an electrostatic chuck illustrated in FIG. 3;

FIG. 6 is a diagram illustrating an example of a plasma reactor including the electrostatic chuck assembly of FIG. 3;

FIG. 7 is a diagram illustrating a wafer etched by the plasma reactor of FIG. 6; and

FIG. 8 is a diagram illustrating an etching rate by each region of a wafer etched by the plasma reactor of FIG. 6.

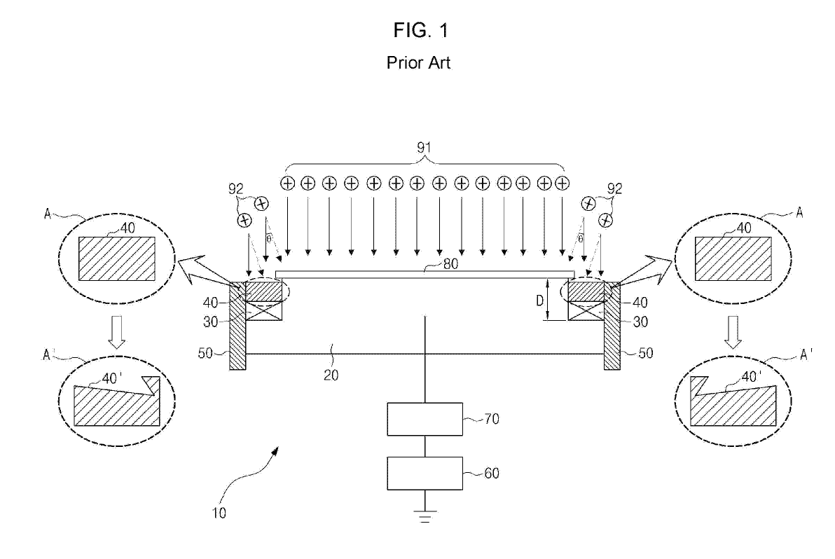

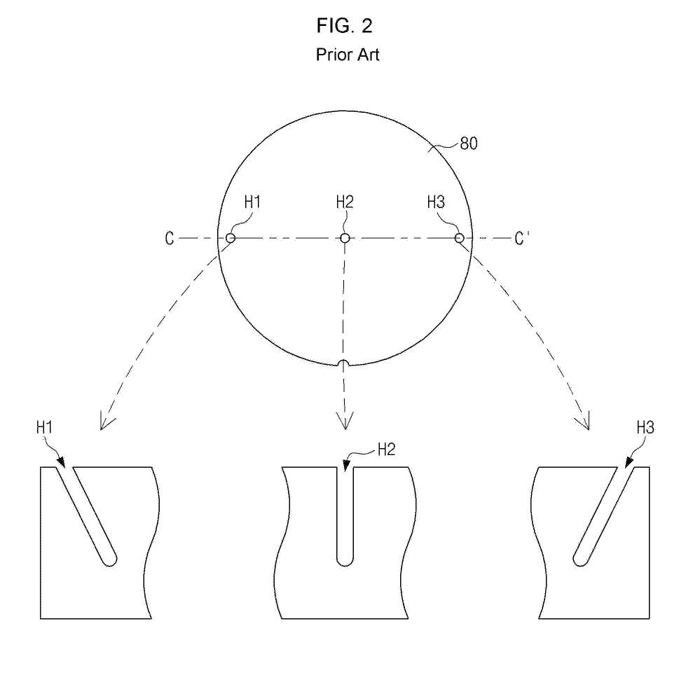

Throughout the drawings, the same drawing reference numerals will be understood to refer to the same elements, features and structures.

### DETAILED DESCRIPTION OF THE INVENTION

Exemplary embodiments of the present invention will now be described in detail with reference to the annexed drawings. In the following description, a detailed description of known functions and configurations incorporated herein has been omitted for conciseness.

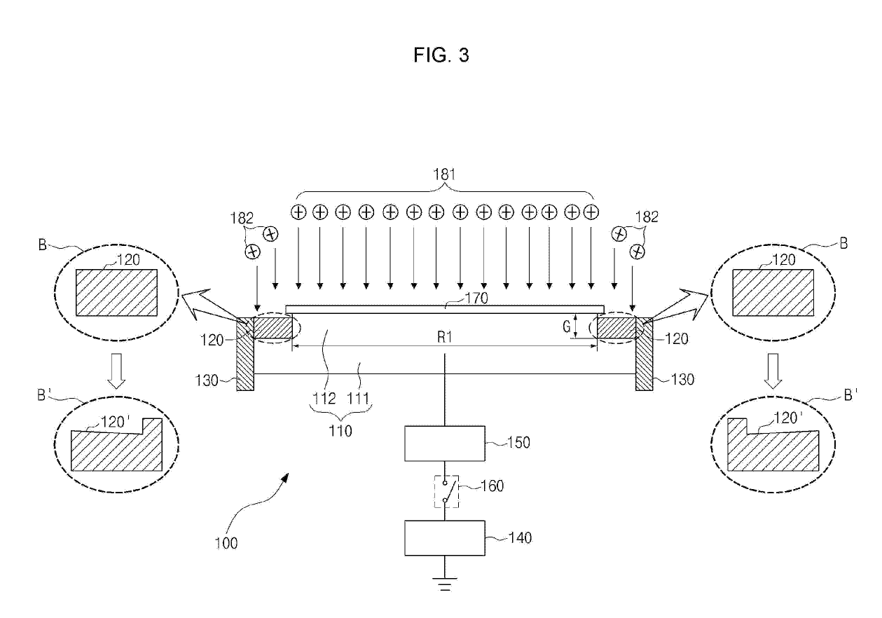

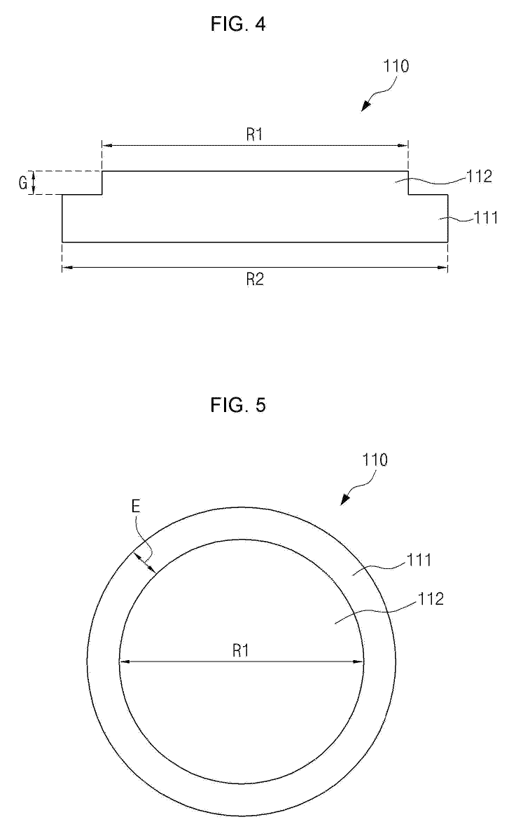

FIG. 3 is a schematic diagram illustrating an electrostatic chuck assembly according to an exemplary embodiment of the present invention. The electrostatic chuck assembly 100 includes an electrostatic chuck 110, an electrostatic chuck cover ring 120, and a cathode assembly cover ring 130. The electrostatic chuck 110 includes a body part 111 and a protrusion part 112. The body part 111 and the protrusion part 112 are each formed in a disk shape (FIG. 5). The protrusion part 112 is formed integrally with the body part 111 and protruded from the body part 111. A diameter (R1) of the protrusion part 112 is less than a diameter (R2 in FIG. 4) of the body part 111.

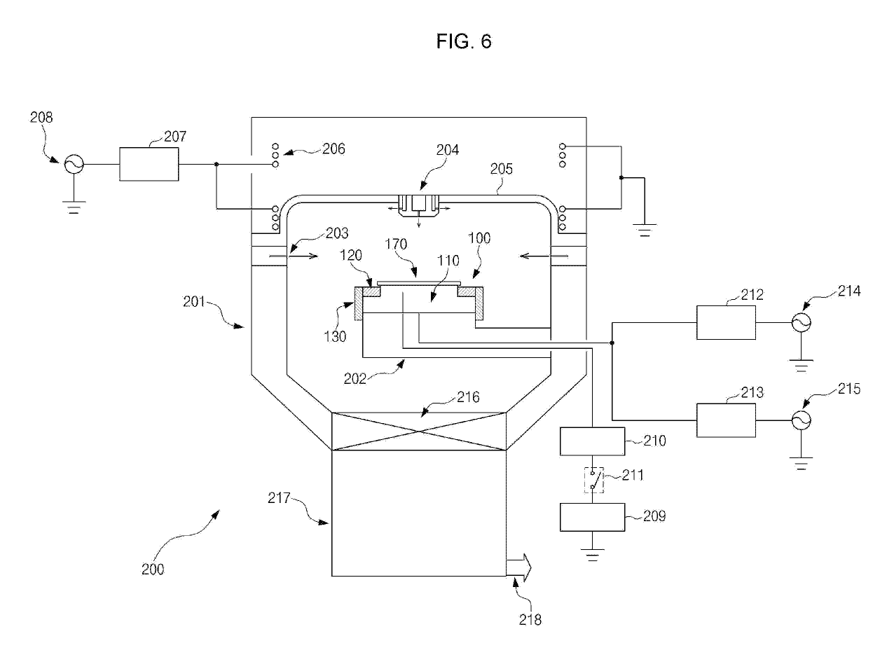

The electrostatic chuck cover ring 120 is disposed to surround an outer circumference of the protrusion part 112. As a plasma reactor 200 (illustrated in FIG. 6) including the electrostatic chuck assembly 100 operates, plasma ions 182 are generated. After the electrostatic chuck cover ring 120 is etched by the plasma ions 182, the electrostatic chuck cover ring 120 has a cut surface of an ‘L’ shape (indicated by a ‘B′’ portion of FIG. 3). For the sake of this, a length (G) of the protrusion part 112 protruded from the body part 111 is set to be in a range of 1.0 mm≦G≦7.0 mm irrespective of a diameter of a target object 170 (e.g., a wafer) safely mounted on an upper surface of the protrusion part 112. The outer circumference of the protrusion part 112 is surrounded only by the electrostatic chuck cover ring 120.

Referring to FIG. 3, as the plasma reactor 200 performs wafer treatment processes repeatedly, a new or non-etched electrostatic chuck cover ring 120 (indicated by the ‘B’ portion) is gradually etched. As a result, as indicated in the ‘B″’ portion of FIG. 3, the electrostatic chuck cover ring 120 is etched to have the cut surface of the ‘L’ shape. The reason why the electrostatic chuck cover ring 120 is etched to have the cut surface of the ‘L’ shape is that, when the target object 170 is etched by the plasma reactor 200, by setting the length (G) of the protrusion part 112 protruded from the body part 111 to the range of 1.0 mm≦G≦7.0 mm, the plasma ions 182 are perpendicularly incident on a surface of the electrostatic chuck cover ring 120. In contrast to this, if the length (G) of the protrusion part 112 protruded from the body part 111 is set to, for example, 10 mm or more, when the target object 170 is etched by the plasma reactor 200, the plasma ions 182 are incident on the surface of the electrostatic chuck cover ring 120 in a slant direction.

The diameter (R1) of the protrusion part 112 represents a diameter of an upper surface of the protrusion part 112 on which the target object 170 is safely mounted. Desirably, the diameter (R1) of the protrusion part 112 is set less by 2.5 mm to 3.5 mm than a diameter of the target object 170. For example, if the target object 170 is equal to a 300 mm wafer, it is ideal that even the diameter (R1) of the protrusion part 112 is equal to about 300 mm but, because there is a handling error of a wafer conveying system, the diameter (R1) of the protrusion part 112 should be always less than a diameter of the wafer. Thus, if the target object 170 is the 300 mm wafer, it is desirable that the diameter (R1) of the protrusion part 112 is set to be in a range of 296.5 mm≦R1≦297.5 mm.

The electrostatic chuck cover ring 120 is disposed to surround the outer circumference of the protrusion part 112 of the electrostatic chuck 110. The electrostatic chuck cover ring 120 protects the body part 111 of the electrostatic chuck 110 from the plasma ions 182 that are generated as the plasma reactor 200 operates. The cathode assembly cover ring 130 is disposed to surround an outer circumference of the electrostatic chuck cover ring 120 and an outer circumference of the body part 111 of the electrostatic chuck 110.

A power supply unit 140 supplies a Direct Current (DC) power source to the electrostatic chuck 110 through an RF noise filter 150. A switch 160 can connect between the power supply unit 140 and the RF noise filter 150. When the power supply unit 140 supplies the DC power source to the electrostatic chuck 110, an attractive force by static electricity is generated in the electrostatic chuck 110 and thus, the target object 170 is fixed to an upper surface of the protrusion part 112.

FIG. 6 is a diagram illustrating an example of a plasma reactor including the electrostatic chuck assembly of FIG. 3. Within a reaction chamber 201 of the plasma reactor 200, a cathode assembly 202 is installed, and the electrostatic chuck assembly 100 is installed on an upper part of the cathode assembly 202. A construction of the electrostatic chuck assembly 100 is identical with a construction described with reference to FIG. 3.

Gas injectors 203 and 204 are installed in a plurality of points of a side surface and top of the reaction chamber 201. By the gas injectors 203 and 204, a reaction gas is injected into the reaction chamber 201. The top of the reaction chamber 201 is comprised of a dielectric window 205. An inductive coil 206 (i.e., a plasma source for generating plasma within the reaction chamber 201) is installed around the dielectric window 205. An RF power supply unit 208 applies an RF power source to the inductive coil 206 through an RF matching network 207. By doing so, a magnetic field is formed in the inductive coil 206. As the magnetic field is formed in the inductive coil 206, plasma ions are generated within the reaction chamber 201.

A switch 211 is connected between the power supply unit 209 and the RF noise filter 210, and the RF noise filter 210 is connected to the electrostatic chuck 110. When the switch 211 turns on, the power supply unit 209 supplies a DC power source to the electrostatic chuck 110 through the RF noise filter 210. Bias impedance matching networks 212 and 213 are connected to a lower electrode (i.e., the cathode assembly 202). A low-frequency RF power supply unit 214 supplies a low-frequency bias RF power to a lower electrode through the bias impedance matching network 212. A high-frequency RF power supply unit 215 supplies a high-frequency bias RF power to the lower electrode through the bias impedance matching network 213. As a result, the low-frequency bias RF power and the high-frequency bias RF power are mixed and applied to the lower electrode (i.e., the cathode assembly 202).

A throttling gate valve 216 and a turbo pump 217 are installed below the reaction chamber 201. An exhaust valve 218 is installed at one side of the turbo pump 217.

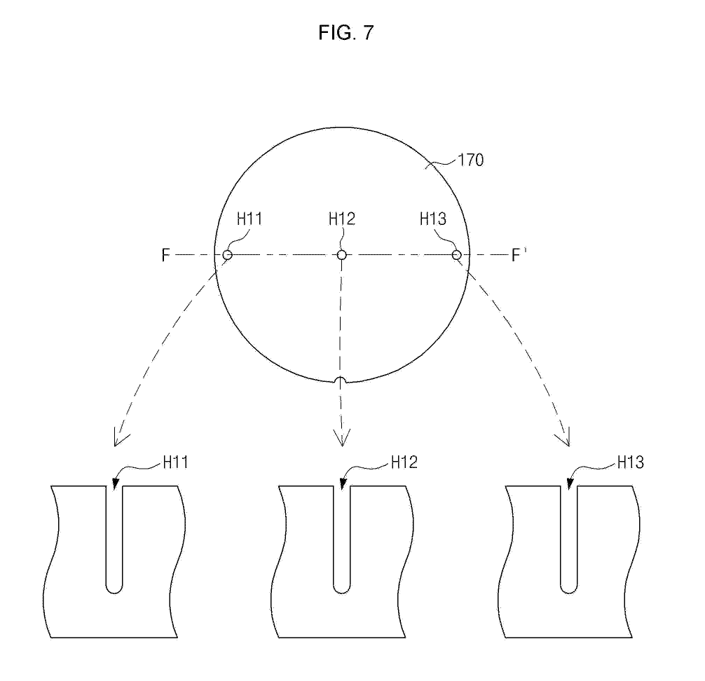

FIG. 7 is a diagram illustrating a wafer etched by the plasma reactor of FIG. 6.

After the wafer 170 is cut along a cutting line F-F′, when viewing its cut surface, a profile of contact holes (H11 to H13) formed in the wafer 170 is illustrated in a lower part of FIG. 7. It can be appreciated from FIG. 7 that the contact holes (H12, and H11 and H13) formed in a center and edge of the wafer 170 have a normal profile perpendicular to a bottom surface (or a surface) of the wafer 170. The reason why the contact holes (H11 and H13) are perpendicularly formed in the bottom surface (or a surface) of the wafer 170 as above is that the length (G) of the protrusion part 112 protruding from the body part 111 is set to be in the range of 1.0 mm≦G≦7.0 mm, and the diameter (R1) of the protrusion part 112 is set less by 2.5 mm to 3.5 mm than the diameter of the target object 170, thus optimizing a structure of the electrostatic chuck 110.

If the diameter (R1) of the protrusion part 112 is too small, at the time of an etching process of the plasma reactor 200, a process quality of the edge of the wafer is deteriorated. To the contrary, if the diameter (R1) of the protrusion part 112 is too large, there is an arcing problem of the electrostatic chuck 110. Accordingly, the diameter (R1) of the protrusion part 112 should be optimized through an experiment accompanying a high cost.

On the other hand, it is most ideal that the length (G) of the protrusion part 112 protruding from the body part 111 is equal to ‘0’. However, in this case, the electrostatic chuck cover ring 120 cannot be installed in the electrostatic chuck 110. If the electrostatic chuck cover ring 120 is not installed in the electrostatic chuck 110, an edge (i.e., an ‘E’ portion of FIG. 5) of the body part 111 of the electrostatic chuck 110 is damaged due to impacts of plasma ions. Thus, the length (G) of the protrusion part 112 protruding from the body part 111 should be maintained as a specific value.

In optimizing the length (G) of the protrusion part 112 protruding from the body part 111, data such as an etching rate of the electrostatic chuck cover ring 120, an etching profile of the target object (i.e., the wafer) 170, an etching rate and etching profile of an edge of the target object 170, etc. should be experimentally obtained. According to the experimental data, when the electrostatic chuck cover ring 120 is of silicon, the etching rate of the electrostatic chuck cover ring 120 is equal to about 0.82 mm/200 Hrs. In conclusion, if securing a Mean Time Between Clean (MTBC) by 200 Hrs or more and simultaneously considering a process error, the length (G) of the protrusion part 112 protruding from the body part 111 should be equal to 1 mm or more.

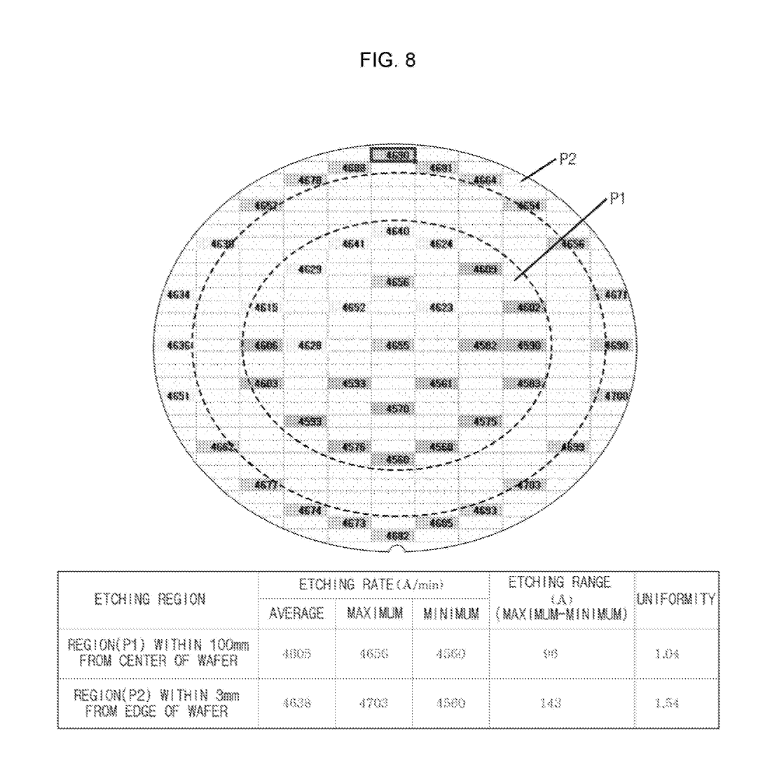

Also, according to the experimental data, when the length (G) of the protrusion part 112 protruding from the body part 111 is equal to 7 mm or less, it is possible to secure a good etching profile of the electrostatic chuck cover ring 120 and a good etching rate (Table of FIG. 8) and etching profile (illustrated in FIG. 7) of the edge of the target object 170. In Table of FIG. 8, an etching range corresponds to a difference between the maximum value and the minimum value of the etching rate, and uniformity can be expressed in Equation below.

$$Uniformity ( \% ) = \frac{\begin{matrix}maximum of etching rate - \\ minimum of etching rate\end{matrix}}{\begin{matrix}maximum of etching rate + \\ minimum of etching rate\end{matrix}} \times 100$$

On the other hand, when the diameter (R1) of the protrusion part 112 is set less by 20.5 mm to 3.5 mm than the diameter of the target object 170 in association with optimization of the length (G) of the protrusion part 112 protruding from the body part 111, it is possible to secure a good etching profile of the electrostatic chuck cover ring 120 and a good etching rate (Table of FIG. 8) and a good etching profile of the edge of the target object 170. On the other hand, a design of the electrostatic chuck 110 and electrostatic chuck assembly 100 is optimized, thereby making it possible to simplify a process kit around the electrostatic chuck 110 and decrease a cost.

While the invention has been shown and described with reference to a certain preferred embodiment thereof, it will be understood by those skilled in the art that various changes in form and details may be made therein without departing from the spirit and scope of the invention as defined by the appended claims.

What is claimed is:

1. An electrostatic chuck assembly for a plasma reactor, comprising:
an electrostatic chuck comprising a body part having a disk shape of a first diameter, and a protrusion part formed integrally with the body part and protruding from the body part, and having a disk shape of a second diameter less than the first diameter;
an electrostatic chuck cover ring disposed to surround an outer circumference of the protrusion part, and protecting the body part of the electrostatic chuck from plasma ions generated as the plasma reactor operates; and
a cathode assembly cover ring disposed at an upper part of the cathode assembly to surround an outer circumference of the electrostatic chuck cover ring and an outer circumference of the body part,
wherein, in order to allow the electrostatic chuck cover ring to have a cut surface of an ‘L’ shape after the electrostatic chuck cover ring is etched by the plasma ions, a length (G) of the protrusion part protruding from the body part is set to be in a range of 1.0 mm≦G≦7.0 mm irrespective of a diameter of a target object safely mounted on an upper surface of the protrusion part.

2. The electrostatic chuck assembly of claim 1, wherein, by setting the length (G) of the protrusion part protruding from the body part in the range of 1.0 mm≦G≦7.0 mm, when the target object is etched by the plasma reactor, the plasma ions are perpendicularly incident on a surface of the electrostatic chuck cover ring, and contact holes formed in an edge of the target object are perpendicular to a surface of the target object.

3. The electrostatic chuck assembly of claim 1, wherein the second diameter of the protrusion part is equal to a diameter of the upper surface of the protrusion part on which the target object is safely mounted, and is set less by 2.5 mm to 3.5 mm than the diameter of the target object.

4. The electrostatic chuck assembly of claim 1, wherein the plasma reactor comprises a plasma source of an inductive coil for generating the plasma ions within a reaction chamber of the plasma reactor.

5. The electrostatic chuck assembly of claim 1, wherein the plasma reactor comprises:
a plasma source of an inductive coil for generating the plasma ions within a reaction chamber of the plasma reactor; and
gas injectors installed in a plurality of points of a top and side of the reaction chamber, and
wherein plasma reaction gas is injected into the reaction chamber by the gas injectors.

6. The electrostatic chuck assembly of claim 1, wherein the plasma reactor comprises a low-frequency Radio Frequency (RF) power supply unit and a high-frequency RF power supply unit, and
wherein, by the low-frequency RF power supply unit and the high-frequency RF power supply unit, a low-frequency bias RF power and a high-frequency bias RF power are mixed and applied to the cathode assembly.
